(19) United States
(12) Patent Application Publication
(10) Pub. No.: US 2005/0174275 A1
(43) Pub. Date: Aug. 11, 2005

(54) Optical disk system with improved playability

(75) Inventors: Hendrik Josephus Goossens, Eindhoven (NL); George Alois Leonie Leenknegt, Eindhoven (NL); Jan Van Helvoirt, Oss (NL); Gheorghe Sorin Stan, Eindhoven (NL); Wooi Liang Chin, Singapore (SG)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V., BA Eindhoven (NL)

(21) Appl. No.: 10/514,596

(22) PCT Filed: May 16, 2003
(86) PCT No.: PCT/IB03/02047

(30) Foreign Application Priority Data
May 21, 2002 (EP) 02076987.3
Oct. 2, 2002 (EP) 02079092.9

(51) Int. Cl. H03M 3/00

(52) U.S. Cl. 341/143

(57) ABSTRACT

An optical disk drive (50) comprises a radial servo system (70) for driving the position of an optical head (52) for scanning an optical disk (10) comprising at least one recording track (11; 12, 13), a focus servo system (80) for controlling the focussing of an optical beam, and a data retrieval system (90) for regenerating the digital data recorded on disk. Operative parameters of the radial servo system (70) and/or focus servo system (80) and/or data retrieval system (90) are frozen or are set to predetermined values as soon as the optical head (52) reaches a predetermined location (17) along a current track (12; 13) which is determined on the basis of a defect entry location (17) along a previous track (11; 12).

The present invention relates in general to optical disk systems and to a method to improve the playability of optical disk audio/video players and computer drives.

Disk-shaped optical storage media are produced in many flavors, as read-only types (e.g. CD-DA, CD-ROM, DD-ROM, DVD-Video, DVD-ROM), write-once recordable types (e.g. CD-R, DD-R, DVD−R, DVD+R), and rewritable types (CD-RW, DD-RW, DVD−RW, DVD+RW, DVD-RAM, Blu-ray Disc). The present invention is applicable in relation to all the above-mentioned types. Since such optical storage media are known per se, a detailed explanation will be omitted here. Suffice it to recall that such optical storage media have at least one record track, either in the shape of a continuous spiral or in the shape of multiple concentric circles, in which data is prerecorded during the manufacturing process for read-only media or can be written by the user for recordable and rewritable media. Further, the present invention is applicable in a process for writing information onto the optical disk as well as in a process for reading information from the optical disk. In the following, the expression “playing” a disk will be used for writing as well as for reading (playback).

Disk drives for playing optical disks are known per se, and a detailed description of such device is not necessary here. Generally, a disk drive comprises an optical head, means for rotating an optical disk, a servo system for driving the optical head such as to follow the track of the rotating disk, and circuitry to retrieve the information written on disk or arrange the user information in a format suitable for being written on disk.

In operation, the servo system obtains information from the optical head and uses it to determine whether or not the optical head is correctly positioned with respect to the track, and if not, what kind of corrective action is needed. This operation takes place automatically by employing control loops and there is no need to adjust the servo settings (in the form of coefficients used to program the integrated circuits) while tracking or focusing with the laser spot.

A problem in this respect is that the optical disk may suffer from mechanical defects like scratches, fingerprints, dust, dirty areas that obscure completely the information layer (the so-called black dots), etc. As a result, the output data stream may contain errors, but also the servo operation may be impaired to such extent that the laser beam “looses” the track and/or focus and needs to be repositioned after the optical head has passed the defect This repositioning operation cannot be performed instantaneously and the data output stream will therefore still contain errors a relatively long time after the optical head has passed the defect.

An important objective of the present invention is to improve the playability of an optical disk system such that the amount of errors in the data output stream, due to such defects, is reduced.

It is also known that the data stream in optical disk systems is separated from the servo signals by means of a high-pass filter or, alternatively, the servo signals are extracted by low-pass filtering from the readout signal. Because the occurrence of any defect on disk induces changes in the readout signal, especially when data retrieval is concerned, the cut-off frequency of the high-pass filter may not appropriately accommodate these changes. This results in distorted signals being passed over to the data retrieval circuitry when the laser beam attempts to read the information beneath black dots, fingerprints, etc. In addition, a data retrieval circuitry programmed to operate upon nominal signals received from disk cannot perform optimally when distorted data signals are present at its input.

U.S. Pat. No. 5,450,388 discloses an optical disk drive where all disk addresses at which defects occur are stored in a defect indication memory. Also stored in a memory is an artificial tracking error signal, or replacement error signal, which is used by the servo system to drive the optical head whenever the optical head is positioned at locations corresponding to the addresses stored in said defect indication memory. This solution, however, requires a large memory. Further, this solution will not help the first time a disk is played.

The present invention is based on the understanding that surface defects usually extend over a relatively large surface area, indicated hereinafter as “surface blur”. This surface blur has a radial extent, such that the surface blur affects a plurality of adjacent tracks. In each subsequent track, the circumferential extent (measured along the length of the track) of the surface blur will be substantially the same as in neighboring tracks. It will be possible to determine and/or calculate which locations and/or addresses correspond to such circumferential extent of a next track before the optical head actually reaches those locations and/or addresses.

Based on this understanding, according to an important aspect of the present invention, expected defect boundaries are determined for a next track, and filter settings of the servo system are amended just before the optical head reaches a calculated defect entry boundary and are reset just after the optical head passes a calculated defect exit boundary.

These and other aspects, features and advantages of the present invention will be further explained by the following description of a preferred embodiment of an optical disk system according to the present invention with reference to the drawings, in which same reference numerals indicate same or similar parts, and in which:

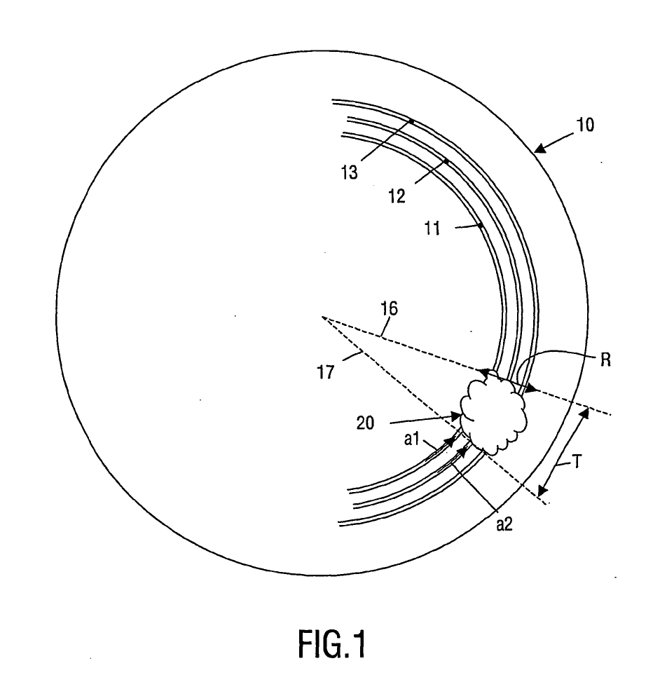

FIG. 1 schematically shows an optical disk;

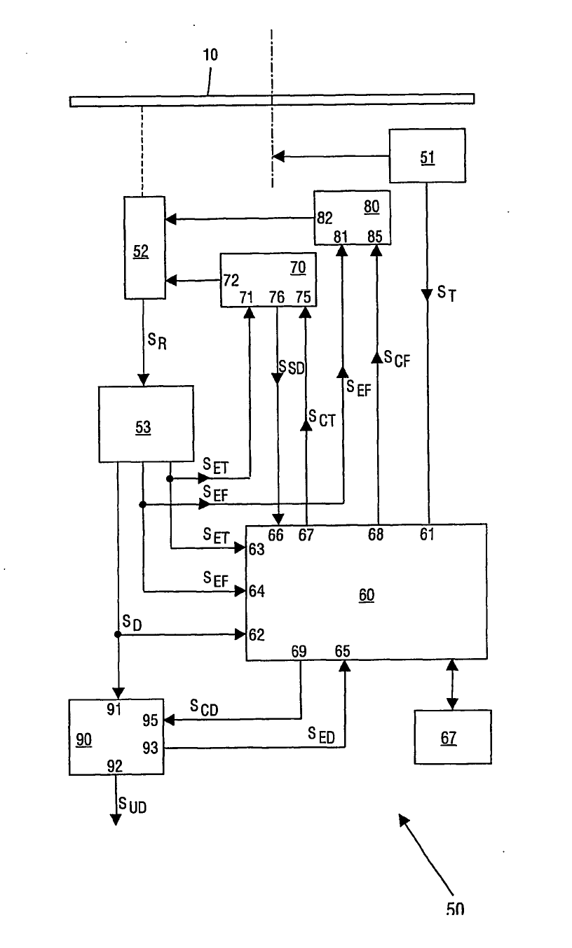

FIG. 2 schematically shows a functional block diagram of an optical disk player or recorder;

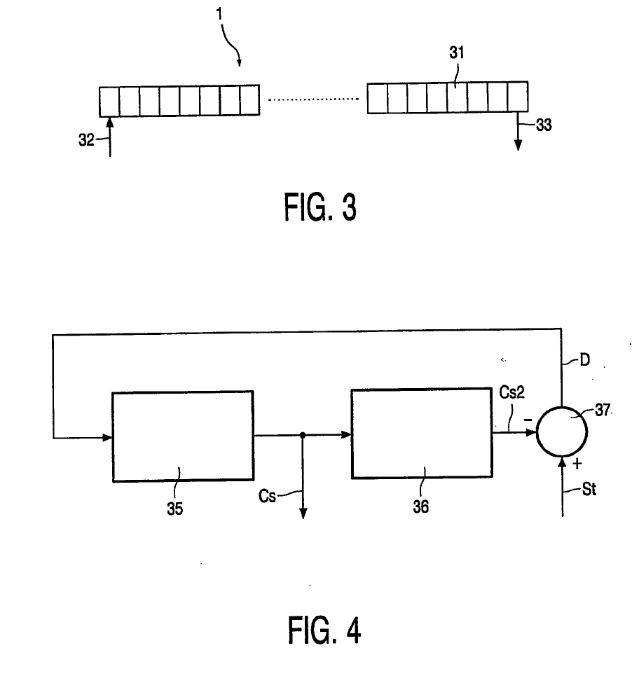

FIG. 3 schematically shows an N bit shift register;

FIG. 4 schematically shows a circuit for generating a clock signal.

FIG. 1 schematically shows an optical disk 10. The optical disk 10 comprises tracks 11, 12, 13 for writing data (these tracks may represent consecutive turns of a unique, continuous spiral-shaped track), and written data can be read from the tracks 11, 12, 13. The track can also be implemented as a plurality of separate, circular tracks, mutually concentric. For the context of the present invention, the type of track is not important. For easy reference, subsequent “turns” of the track (i.e. portions of 360°) will hereinafter each be indicated by the phrase “track”. Thus, the phrase “track” may be used for each separate circular track, or for a 360° portion of a spiral-shaped track. In FIG. 1, three tracks 11, 12, 13 are shown.

FIG. 2 schematically shows an optical disk player device 50 but, as will become clear throughout this document, the invention refers equally well to optical disk recorders. The disk player 50 comprises means (not shown) for receiving the optical disk 10, and rotating means 51, typically comprising a motor, for rotating the optical disk 10 at a predetermined rotational speed. The predetermined rotational speed can be constant resulting in a Constant Angular Velocity drive (CAV) or the rotational speed can be variable such as in Constant Linear Velocity Drives (CLV). Also combinations of CLV and CAV are possible. Preferably, the rotating means 51 are designed for generating a signal S_{T} indicative of an amount of rotation. For instance, the signal S_{T} may be a pulse signal, each pulse corresponding to a predetermined angular distance, for instance corresponding to 1°. Since such rotating means 51 are well known, and means for producing such signal S_{T} are also known, it is not necessary here to explain these means in more detail.

The disk player 50 further comprises an optical head 52, arranged for scanning the surface of the rotating disk 10 with an optical beam, and to derive a read signal SR from the reflected beam. Since such optical head may be a prior art device, it is not necessary here to explain its construction and operation in more detail.

As mentioned, the optical disk 10 comprises a predefined track structure. The read signal SR will contain information in relation to the track structure itself; more particularly, the read signal SR will contain information as to whether the optical beam from the optical head 52 is aligned with a track and whether the optical beam is correctly focussed on the track. A signal processor 53 receives the read signal SR and derives therefrom a first error signal SET, which indicates the alignment of the optical head 52 with a track, and a second error signal SEF, which indicates the focussing of the optical beam on the track. If the optical head 52 is exactly on track and the laser beam is exactly in focus, the corresponding error signals SET and SEF equal zero. If the optical head 52 is off track or if any defocusing occurs, the magnitude of the corresponding error signals SET and SEF represent a measure of the amount of misalignment or defocusing, respectively, while the polarity of the error signals SET and SEF represents the direction of misalignment or defocusing. Since such error signals are known per se, it is not necessary here to explain them in more detail.

A first servo system or radial servo system 70 receives the track error signal SET at a first input 71. The radial servo system 70 is designed to generate, at an output 72, a position control signal controlling the radial position of the optical head 52 such as to force the optical head to follow the track. Since such a servo system is known, it is not necessary here to explain its construction and operation in more detail. However, it is noted that the signal processor 53 may be integrated with the radial servo system 70.

A second servo system or focus servo system 80 receives the focus error signal SEF at a first input 81. The focus servo system 80 is designed to generate, at an output 82, a focus control signal controlling the focussing of the optical beam such as to keep the optical beam focussed on the track. Since such a focus servo system is known, it is not necessary here to explain its construction and operation in more detail. However, it is noted that the focus servo system 80 may be integrated with the radial servo system 70.

The optical disk 10 may be a blank disk, i.e., a disk without data recorded thereon. In that case, the read signal SR relates to the track only. If the optical disk 10 is a recorded disk, i.e., a disk with data recorded thereon, the read signal SR also contains data information. From this read signal SR, the signal processor 53 also derives a data signal SD. As will be clear to a person skilled in the art, the data signal usually includes location. information such as track number, block number, etc. The data signal SD is received by a data retrieval system 90 at a first input 91 thereof This data retrieval system 90 is designed to retrieve user data SUD from the data signal SD, and to provide this user data SUD at an output 92. A complementary role of the data retrieval block 90 is to extract from a signal SD retrieved from a blank disk not the user data (as this is not available yet) but the addressing information needed to position the laser spot at the desired recording position. Associated with this addressing information is a fixed clock frequency that characterizes the so-called wobble signal and is used by the block 90 during the recording process. The invention refers, hence, equally well to optical playback and recording systems in which the track to be read out or recorded, respectively, is obscured by some surface defects. Since a data retrieval system 90 is known for both read-only and recordable systems, it is not necessary here to explain its construction and operation in more detail.

The optical disk 10 illustrated in FIG. 1 contains a surface defect 20, which affects a certain surface area of the disk 10. Considering polar coordinates, the defect 20 has a radial size indicated by arrow R, and an angular size indicated by arrow T. In angular direction, the defect 20 is confined between radial lines 16 and 17.

Due to this defect, the read signal SR is distorted, and can not be used any more by the radial servo system 70, nor can it be used by the focus servo system 80, nor can it be used by the data retrieval system 90. For instance, the data signal SD typically contains ) a clock frequency component, and the data retrieval system 90 comprises a phase-locked loop (PLL) locking on said clock frequency component. When the read signal SR is distorted, the PLL system may get out of lock.

Normally, in order for the system to be able to respond to vibrations, it is desirable that the servo systems 70, 80 as well as the PLL of the data retrieval system 90 are very fast. In the case of a defect 20, the fast characteristic of the servo systems 70, 80 and PLL are disadvantageous, because now both will try rapidly to recover from off-track and/or defocus and/or lost phase-lock conditions, which will be impossible due to the read signal SR being distorted. As a result, the radial servo system 70 may, uncontrollably, drive the optical head 52 away from the actual track in its effort for recovery, so that, when the optical head 52 has passed the defect 20, the optical head 52 is way off track and it takes some time for the radial servo system 70 to recover and bring the optical head 52 back to the desired track. Similarly, the focus servo system 80 may, uncontrollably, drive the laser beam out of focus so that, when the optical head 52 has passed the defect 20, it takes some time for the focus servo system 80 to recover and bring the laser beam back to focus. In turn, the data signal becomes corrupted and drives the PLL out of lock. For the data retrieval system 90, losing the phase lock will result in errors introduced in the bit pattern regenerated from disk, which may exceed the capability of the error detection and correction circuitry to recover the missing information. This all adds up to the length of track not read by the optical head: this length, in fact, may be significantly longer than the length actually affected by the defect 20.

In the optical disk system according to the present invention, these disadvantages of prior art device are reduced or even eliminated. Briefly stated, the defect as experienced in one track is used as a prediction for the presence of a defect in the next track, and at the predicted defective track portion the servo systems 70, 80 as well as the locked state of the PLL are “frozen”, as will be explained in the following. A control unit 60 has a first input 61 coupled to receive the position signal ST from the said rotation means 51, a second input 62 coupled to receive the data signal SD from the signal processor 53, a third input 63 coupled to receive the track error signal SET from the signal processor 53, a fourth input 64 coupled to receive the focus error signal SEF from the signal processor 53, and a fifth input 65 coupled to receive a data error signal SED generated by the data retrieval system 90 at a second output 93 thereof. As will be clear to a person skilled in the art, the control unit 60 may alternatively be integrated with the signal processor 53 and/or integrated with the radial servo system 70 and/or integrated with the focus servo system 80 and/or integrated with the data retrieval system 90.

FIG. 1 clearly shows that the defect 20 affects more than just one track; in fact, in the illustration of FIG. 1, the defect 20 affects all three tracks 11, 12, 13. The respective affected portions of the tracks 11, 12, 13 substantially correspond to said lines 16, 17.

In general, when considering all tracks affected by a defect, their respective affected portions will not all have the same angular extent. If the defect has a more or less round shape, like the defect 20 illustrated in FIG. 1, the affected portion of a track which is affected by the central portion of the defect will be relatively long, whereas the affected portion of a track which is affected by an edge portion of the defect will be relatively short. However, due to the fact that the radial pitch of the tracks is extremely small, the angular coordinates of the edges of the affected portions of adjacent tracks will be almost identical.

According to an important aspect of the present invention, the above is utilized as follows. Consider the optical head 52 (not shown in FIG. 1) following the first track 11 in counter-clockwise direction, approaching the defect 20 for the first time, as indicated by arrow a1. When the optical head meets the defect 20, the angular position (radial line 17) of the entry edge of the defect 20 will be known to the control unit 60. The control unit 60 will monitor the track error signal SET and/or the focus error signal SEF and/or the data error signal SED and/or the data signal SD, and will recognize from the deterioration of any of these signals that the optical head has encountered a defect. The control unit 60 will also monitor the data signal SD and/or the position signal ST, from which signal(s) the control unit 60 can derive the location of the entry boundary of the defective track portion. The control unit 60 will store this location in an associated memory 67. By way of example, the information can be recorded as compact disk (CD) subcode timing or digital versatile disk (DVD) header, since they are better for controlling the exact position along the track spiral.

Similarly, when the optical head leaves the defect 20, the angular position (radial line 16) of the exit edge of the defect 20 can be known, and the control unit 60 will also store this location in the associated memory 67.

FIG. 2 also illustrates that the radial servo system 70 may comprise a servo defect detector, such that it may be capable of generating a servo defect detector signal SSD at a servo defect output 76, which is coupled to a servo defect input 66 of the control unit 60. By way of example, such servo defect detector may be based on monitoring the signal magnitudes or by monitoring phase differences between a reference signal and the one retrieved from disk, such as is already known in the art. Thus, the radial servo system 70 informs the control unit 60 that the optical head 52 has encountered a defect.

Preferably, the control unit 60 is programmed to assume that a defective track portion is entered as soon as either one of the data signal SD, the track error signal SET, the focus error signal SEF, the data error signal SED, or the servo defect detector signal SSD indicates a defect.

One 360° rotation of the disk 10 further, the optical head again approaches the defect 20, now following the second track 12, as indicated by arrow a2. It will now be expected or predicted by the control unit 60 that this second track 12 is also affected by the same defect 20 between the same two angular positions (lines 17 and 16, respectively).

The control unit 60 has a first control output 67, coupled to a control input 75 of the radial servo system 70. The control unit 60 has a second control output 68, coupled to a control input 85 of the focus servo system 80. The control unit 60 has a third control output 69, coupled to a control input 95 of the data retrieval system 90. The control unit 60 is adapted to generate at its control outputs 67 and/or 68 and/or 69 suitable control signals SCT, SCF, SCD, respectively, and the radial servo system 70, the focus servo system 80, and the data retrieval system 90, respectively, are responsive to these control signals to set at least one of their operative parameters to a predetermined value, independent of the read signal.

This predetermined value may be a value which changes (increases or decreases) during at least part of the travel of the optical head 52 over the defect 20. This may, for instance, be suitable in the case of an operative parameter being a detector threshold level. However, for most operative parameters, with a view to the very brief travel time over the defect, it is more efficient if said predetermined value is a constant value.

Such constant value may be determined in different ways. One option for determining a constant value for an operative parameter is to freeze such operative parameter to the value immediately before receiving said control signal SCT or SCF or SCD, respectively, i.e., immediately before entering the defective area. Examples of such operative parameters for which this option is a suitable option are the gain settings of the automatic control loops that keep the laser beam on track and in focus, the corner frequencies of various filters, integrators, and differentiators in the system, etc. For the path followed by the data signal, the controller 60 may fix the PLL gain and operating bandwidth.

Another option for determining a constant value for an operative parameter is to set such operative parameter to a predetermined optimum value, which earlier has been predetermined to be optimal in the case of reading areas with defects from disk. An example of such operative parameter for which this option is a suitable option is the cut-off frequency of the high-pass filter that separates the data signal from the low-frequency components present in the readout signal.

Such predetermined optimum constant value may have been determined by the manufacturer, and stored in a memory part of the control unit 60 or the radial servo system 70 or the focus servo system 80 or the data retrieval system 90, respectively. Another possibility is that the optical disk drive system has self-learning capabilities and is adapted to determine such optimum constant values during operation.

Thus, the control unit 60, in anticipation of the defective portion of this second track 12, generates its control signals SCT, SCF, SCD, respectively, and settings of the servo control and data retrieval circuitry are set to predetermined, preferably constant values, independent of the read signal, as soon as the optical head 52 reaches the calculated entry boundary 17 of the defective portion of the second track 12. Since such settings are now constant, or at least predetermined, they can not be affected by readout signals from the defective portion. As a result, the position of the optical head will remain on track to a good approximation, the laser beam will remain in focus, and the data retrieval circuitry will limit the generation of erroneous bits. In addition, the duration of a possibly necessary recovery procedure after passing the defective area will be relatively short.

The control unit 60 continuously monitors its input signals. If the control unit 60 finds, from the data signal SD, or the track error signal SET, or the focus error signal SEF, or the data error signal SED, or the servo defect detector signal SSD, that the optical head 52 reaches a defect before the predetermined entry boundary 17, it will generate its control signals SCT, SCF, SCD, respectively, earlier than the calculated moment, and it will store the earlier location into its memory. If the control unit 60 finds, from the data signal SD, or the track error signal SET, or the focus error signal SEF, or the data error signal SED, or the servo defect detector signal SSD, that the optical head 52 actually reaches the defect later than calculated, it will store this later location into its memory. Thus, at all times, the expected location of the entry boundary 17 of a next track (13) is determined on the basis of the actual location of the entry boundary of the present track (12). The same applies, mutatis mutandis, to the exit boundary 16.

Along a track spiral, the expected linear location L2 of the entry boundary 17 of the defect can be calculated from the actual location L1 of the entry boundary of the present track, in accordance with the following formula:

$${L}_{2} = {L}_{1} + π ( 2 \sqrt{{R}_{i n}^{2} + \frac{{L}_{1} q}{π}} + q )$$

where:
Rᵢₙ represents the radius at which the data area starts, and q is the track pitch.

The position L2 can be calculated for various optical disk systems by taking into account the subcode timing or the length of a sector (or ECC block) for CD and DVD, respectively. The same applies to the exit boundary 16.

Instead of calculating the expected entry location L2 also a shift register 30 as depicted in FIG. 3 can be used to determine the expected entry location L2. The shift register 30 is a memory of N bits 31, where each bit 31 represents the presence of a defect in the i-th section of one revolution of a track. The i-th position in the memory represents an optical disk angle. The number N defines the resolution with which the angular position of a defect within one revolution can be stored. A high level bit is written into the memory when the control unit 60 establishes that a defective track portion is encountered, a low level bit otherwise. Of course these levels can be reversed such that a low level bit indicates a defect. The bits are written into the shift register 30 at a location indicated by a write pointer 32, and the bits are read out the shift register 30 at a location indicated by a read pointer 33. Now the contents of the shift register 30 is shifted to the right at the pace defined by a clock signal Cs which is derived from the optical disks angular velocity. Any signal that indicates the angular position of the optical disk will suffice to function as the clock signal Cs. After one revolution of the disk the defect information should be read by the read pointer 33. The clock signal Cs should thus have a frequency of N periods per revolution of the disc.

The clock signal Cs can be derived from the disk velocity by a circuit as depicted in FIG. 4. A phase locked loop 35 is locked on a difference signal D. The difference signal D is generated by the subtraction means 37 which subtracts a second clock signal Cs2 from a position signal S_{T} of the rotating means. The rotating means 51 should thus be provided with a spindle motor for rotating the optical disk which has a position signal S_{T} output. The position signal S_{T} can be a so called tacho output. The tacho output is a signal indicating the angular position of the spindle motor and thus the optical disk. The tacho output can consist of a series of pulses where each pulse indicates that the spindle motor has rotated a certain amount. The phase locked loop 35 generates the clock signal Cs. The clock signal Cs is divided by a divider 36 The divider 36 outputs the second clock signal Cs2 with a lower frequency than the clock signal Cs. The second clock signal Cs2 is subtracted from the position signal ST by the subtracting means 37 thereby generating the difference signal D. The divider divides the clock signal Cs such that the clock frequency of the clock signal Cs is increased to the needed frequency of N per revolution. The shift register 30, which is read out in a pace controlled by the clock signal Cs, is clocked in a pace of N bits per revolution so that after one revolution all the bits 31 are read out.

A large advantage of this set up is that we can look ahead if a defect will deteriorate the servo signals. When the read pointer not only looks at the current i-th position but also one or more bits earlier in the shift register 30 (at N-j where j={1,2 . . . } and where j is small, i.e. j<<N) this information can be used to react on a possible defect before it starts. When a jump is performed the shift register 30 should be erased. Furthermore, an other advantage of the use of the N bit shift register 30 as a memory for the defect entry location 17 is that this memory can be relatively small as only 1 bit represents a location as compared to a memory where the location is stored by storing an address of that location. Therefore, implementing the embodiment using the N bit shift register 30 is relatively simple and economical.

It should be clear to a person skilled in the art that the present invention is not limited to the exemplary embodiments discussed above, but that other variations and modifications are possible within the protective scope of the invention as defined in the appending claims.

For instance, instead of separate radial and focus servo controllers it is possible to have one common servo controller. Further, the functions of servo controllers (70, 80), data retrieval circuitry (90), and control logic (60) may be implemented in one integrated system.

Further, it may be possible that the predetermined settings of one or more operative parameters are inadequate, such that recovery of the system after passing the defect takes too much time. Therefore, it is possible that a next time the optical head approaches the defect, at least one optical parameter is set to a value different from the value used a previous time. It may even be that such next approach involves a retry in respect of the same track. It may be that subsequent settings are predetermined as well, or that a next setting is calculated from the previous setting according to a predetermined algorithm.

Further, it may be that the predetermined settings of an operative parameter depend on rotational speed of the optical disk and/or other operative conditions. It may also be that, for a specific operative parameter, the predetermined setting at an inner track differs from the predetermined setting at an outer track.

Further, in the case that the value of an operative parameter is changed from its value just before entering the defect to a different predetermined value, this change may be an abrupt jump but it may also be a gentle change taling a finite amount of time. The same applies mutatis mutandis to the restoring of the optical parameter after the optical head has passed the defect.

1. Method for controlling a radial servo system, a focus servo system, and a data recovery system in an optical disk drive comprising an optical head for scanning an optical disk comprising at least one recording track, wherein at least one operative parameter of the radial servo system and/or focus servo system and/or data recovery system is set to a predetermined value as soon as the optical head reaches a predetermined location along a current track which is determined on the basis of a defect entry location along a previous track.

2. Method according to claim 1, wherein the defect entry location along the previous track is stored in N bit shift register by setting bits in the N bit shift register, where each bit of the shift register represents an angular position of the optical disk, and wherein the predetermined location is determined by reading the bits in the N bit shift register.

3. Method according to claim 2, wherein the N bit shift register is read out by shifting the bits in the shift register at a pace defined by a clock signal related to a velocity of the optical disk and where one revolution of the optical disk corresponds with shifting N bits.

4. Method according to claim 3, wherein the clock signal is derived by executing the steps of:
locking by a phase locked loop circuit to a difference signal of a position signal of rotating means for rotating the optical disk and a second clock signal, where the phase locked loop circuit outputs the clock signal;
generating the second clock signal by dividing the clock signal such that a frequency of the clock signal is increased to a frequency of N per revolution of the optical disk.

5. Method according to one of the claims 1 to 4, wherein said at least one operative parameter is fixed to a constant value.

6. Method according to claim 5, wherein said at least one operative parameter is frozen to its value immediately before reaching said predetermined location along said current track.

7. Method according to claim 5, wherein said at least one operative parameter is set to a predetermined constant value.

8. Method according to one of the claims 1 to 4, wherein said at least one operative parameter is changed during at least part of the travel of the optical head from a defect entry location to a defect exit location.

9. Method according to any of the previous claims, wherein, in subsequent occurrences, said predetermined value of a next occurrence differs from said predetermined value of a previous occurrence.

10. Method according to any of the previous claims, wherein, after the optical head has passed a defect exit location, said at least one operative parameter is restored to the value it had immediately before reaching said predetermined location along said current track.

11. Optical disk player, adapted for receiving an optical disk comprising tracks, and comprising:
rotating means for rotating the optical disk;
an optical head, arranged for generating an optical beam and for scanning with this beam a surface of the rotating disk, and to derive a read signal from the reflected beam;
a radial servo system respondent to a track error signal for controlling the radial position of the optical head such as to force the optical head to follow a track;
a focus servo system respondent to a focus error signal for controlling the focussing of the optical beam such as to keep the optical beam focussed on the track;
a data retrieval system for regenerating the user data bits inscribed on written disks or the addressing and wobble frequency information inscribed on blank disks;
and a control unit adapted to control the radial servo system and/or the focus servo system and/or the data retrieval system such that at least one operative parameter of the radial servo system and/or the focus servo system and/or the data retrieval system is set to a predetermined value whenever the control unit finds that the optical head encounters a defect.

12. Optical disk player according to claim 11, wherein the control unit is adapted to control the radial servo system and/or the focus servo system and/or the data retrieval system such that said at least one operative parameter is fixed to a constant value.

13. Optical disk player according to claim 12, wherein the control unit is adapted to control the radial servo system and/or the focus servo system and/or the data retrieval system such that said at least one operative parameter is frozen to its value immediately before the optical head encounters said defect.

14. Optical disk player according to claim 12, wherein the control unit is adapted to control the radial servo system and/or the focus servo system and/or the data retrieval system such that said at least one operative parameter is set to a predetermined constant value when the optical head encounters said defect.

15. Optical disk player according to claim 11, wherein the control unit is adapted to control the radial servo system and/or the focus servo system and/or the data retrieval system such that said at least one operative parameter is changed during at least part of the travel of the optical head from a defect entry location to a defect exit location.

16. Optical disk player according to any of claims 11-15, wherein the control unit is adapted to control the radial servo system and/or the focus servo system and/or the data retrieval system such that, in subsequent occurrences, said predetermined value of a next occurrence differs from said predetermined value of a previous occurrence.

17. Optical disk player according to any of claims 11-16, wherein the control unit is adapted to control the radial servo system and/or the focus servo system and/or the data retrieval system such that, after the laser spot exits the defective area, said at least one operative parameter is restored to the value used before the optical head encountered said defect.

18. Optical disk player according to any of claims 11-17, further comprising a signal processor coupled to receive the read signal from the optical head and adapted to derive therefrom a track error signal.

19. Optical disk player according to claim 18, wherein the radial servo system has a first input coupled to receive the track error signal.

20. Optical disk player according to claim 18 or 19, wherein said control unit has an input coupled to receive the track error signal.

21. Optical disk player according to any of claims 11-20, further comprising a signal processor coupled to receive the read signal from the optical head and adapted to derive therefrom a focus error signal.

22. Optical disk player according to claim 21, wherein the focus servo system has a first input coupled to receive the focus error signal.

23. Optical disk player according to claim 21 or 22, wherein said control unit has an input coupled to receive the focus error signal.

24. Optical disk player according to any of claims 11-23, further comprising a signal processor coupled to receive the read signal from the optical head and adapted to derive therefrom a data signal, wherein said control unit has an input coupled to receive the data signal.

25. Optical disk player according to claim 24, wherein said data retrieval system is coupled to receive the data signal from the signal processor and is adapted to derive therefrom a data error signal, wherein said control unit has an input coupled to receive the data error signal.

26. Optical disk player according to any of the claims 11-25, wherein the servo system comprises a servo defect detector, and is capable of generating a servo defect detector signal at a servo defect output, and wherein the control unit has a servo defect input coupled to receive the servo defect detector signal from said servo defect output of the servo system.

27. Optical disk player according to any of the claims 11-26, wherein the control unit has a first control output coupled to a control input of the radial servo system, a second control output coupled to a control input of the focus servo system, and a third control output coupled to a control input of the data retrieval system.

28. Optical disk player according to any of the claims 11-27, wherein said rotating means are designed for generating a position signal indicative of an amount of rotation, and wherein the control unit has an input coupled to receive this position signal.

29. Optical disk player according to claim 25 or any of the claims 26-28 as far as they are dependent on claim 25, wherein the control unit is adapted to monitor at least one of the track error signal, the focus error signal, the data error signal, the data signal;
wherein the control unit is adapted to find that the optical head has reached an entry location of a defective track portion of the current track if at least one of the monitored signals deteriorates;
wherein the control unit is adapted to determine an expected entry location of a defective track portion of the next track being radially aligned with said entry location of said defective track portion of said current track;
wherein the control unit is adapted to generate a control signal controlling the radial servo system on the optical head reaching said expected entry location of the next track, the radial servo system being responsive to this control signal to set at least one of its operative parameters to a predetermined value, independent of the read signal;
and/or wherein the control unit is adapted to generate a control signal controlling the focus servo system on the optical head reaching said expected entry location of the next track, the focus servo system being responsive to this control signal to set at least one of its operative parameters to a predetermined value, independent of the read signal;
and/or wherein the control unit is adapted to generate a control signal controlling the data retrieval system on the optical head reaching said expected entry location of the next track, the data retrieval system being responsive to this control signal to set at least one of its operative parameters to a predetermined value, independent of the read signal.

30. Optical disk player according to claim 29, wherein the control unit comprises an N bit shift register and wherein the control unit is adapted to store the entry location of a defective track portion of the current track by setting bits in the N bit shift register where each bit of the shift register represents an angular position of the optical disk, and wherein the expected entry location of the next track, is determined by reading the bits in the N bit shift register.

31. Optical disk player according to claim 30, wherein the control unit is adapted to read out the N bit shift register by shifting the bits in the shift register at a pace defined by a clock signal related to a velocity of the optical disk and where one revolution of the optical disk corresponds with shifting N bits.

32. Optical disk player according to claim 31, wherein said rotating means are designed for generating a position signal indicative of an amount of rotation, and wherein the control unit has an input coupled to receive this position signal and wherein the control unit further comprises:
a phase locked loop circuit for locking to a difference signal of the position signal and a second clock signal, where the phase locked loop circuit outputs the clock signal;
divider for outputting the second clock signal by dividing the clock signal such that a frequency of the clock signal increases to a frequency of N per revolution of the optical disk.

33. Optical disk player according to any of the claims 29 to 32, wherein said predetermined value is a constant value.

34. Optical disk player according to claim 33, wherein said constant value is at least substantially equal to the operative value immediately before reception of the corresponding control signal.

35. Optical disk player according to claim 33, wherein said constant value is a predetermined constant value, which may have been determined at a design stage of the apparatus or calculated during the operation of the apparatus.

36. Optical disk player device according to any of claims 33-35, wherein, in respect of the next track, the control unit is adapted to generate said control signal if the control unit finds that the optical head has reached an entry location of a defective track portion of the next track before the expected entry location.

37. Optical disk player device according to any of claims 33-36, wherein the control unit is adapted to calculate said expected entry location of a defective track portion of the next track on the basis of the actual entry location of a defective track portion of the current track in accordance with the following formula:
$${L}_{2} = {L}_{1} + π ( 2 \sqrt{{R}_{i n}^{2} + \frac{{L}_{1} q}{π}} + q )$$
where:
Rᵢₙ represents the inner radius at which the data area starts, and
q is the track pitch.
